(19) United States
(12) Patent Application Publication
(10) Pub. No.: US 2015/0163961 A1
(43) Pub. Date: Jun. 11, 2015

(54) Power Conversion Apparatus

(71) Applicant: Hitachi Automotive Systems, Ltd., Hitachinaka-sh, Ibaraki (JP)

(72) Inventors: Yosei Hara, Hitachinaka (JP); Morio Kuwano, Hitachinaka (JP)

(73) Assignee: Hitachi Automotive Systems, Ltd., Hitachinaka-shi, Ibaraki (JP)

(21) Appl. No.: 14/419,997

(22) PCT Filed: Jul. 24, 2013
(86) PCT No.: PCT/JP2013/069971

§ 371 Date: Feb. 6, 2015

(30) Foreign Application Priority Data
Sep. 28, 2012 (JP) 2012-215456

(51) Int. Cl. H05K 7/20

(52) U.S. Cl. CPC H05K 7/20218

(57) ABSTRACT

A power conversion apparatus includes power semiconductor modules (300U, 300V, 300W), a first flow path forming body (110) that forms a first flow path, a second flow path forming body (401) that forms a second flow bath, a first base plate (400) for mounting the second flow path forming body thereon, a drive circuit board (200), and a case (101). The drive circuit board (200) is provided so that a mounting surface of the drive circuit faces a side wall of the second flow bath forming body (401). The second flow path forming body (401) forms a housing space for housing the power semiconductor modules (300U, 300V, 300W). Further, the second flow path forming body (401) forms an insertion opening that leads to the housing space, on a side wall facing the mounting surface of the drive circuit. The power semiconductor modules (300U, 300V, 300W) have a control terminal that is connected to the &rive circuit board (200) by passing through the insertion opening. Then, the first flow path forming body (110) is fixed to the case (101). Because of this structure, it is possible to achieve further improvement in the ease of assembly of the power conversion apparatus.

### TECHNICAL FIELD

The present invention relates to a power conversion apparatus used to convert DC power to AC power or to convert AC power to DC power, and more particularly to a power conversion apparatus used for hybrid electric vehicles and electric vehicles.

### BACKGROUND ART

With the reduction in size of hybrid electric vehicles or electric vehicles, there is a demand for reducing the size of the power conversion apparatus used in such vehicles. Further, it is required to achieve both the reduction in size of the power conversion apparatus as well as the improvement in the ease of assembly. In other words, requirements such as ensuring a space in the power conversion apparatus to insert tools or other equipment for the assembly of the power conversion apparatus run counter to the reduction in size of the power conversion apparatus.

Patent Literature 1 describes a method for connecting a terminal of a power semiconductor module and a terminal of a capacitor module by welding, as well as a method for connecting a driver circuit board and a power semiconductor module by solder material after the power semi conductor module and the capacitor module are provided in the power conversion apparatus.

However, further improvement in the ease of assembly of the power conversion apparatus is required.

### CITATION LIST

### Patent Literature

Patent Literature 1: Japanese Unexamined Patent Application Publication No. 2011-217550

### SUMMARY OF INVENTION

### Technical Problem

Accordingly, an object of the present invention is to further improve the ease of assembly of power conversion apparatus.

### Solution to Problem

A power conversion apparatus according to the present invention includes: a power semiconductor module including a power semiconductor element for converting a direct current to an alternating current; a first flow path forming body that forms a first flow path for allowing cooling refrigerant to flow therethrough; a second flow path forming body that forms a second flow path for allowing the cooling refrigerant to flow therethrough; a first base plate for mounting the second flow path forming body thereon; a drive circuit board mounted with a drive circuit so output a drive signal to drive the power semiconductor element; and a case for housing the power semiconductor module, the first flow path forming body, the second flow path forming body, the first base plate, and the drive circuit board. The drive circuit board is provided so that the mounting surface of the drive circuit faces a side wall of the second flow path forming body. The second flow path forming body forms a housing space to house the power semiconductor module. Further, the second flow path forming body forms an insertion opening that leads to the housing space, on the side wall facing the mounting surface of the drive circuit. The power semiconductor module has a control terminal that is connected to the drive circuit board by passing through the insertion opening The first flow path forming body is fixed to the case. At the same time, the first flow path forming body forms an opening that leads to the first flow path. The first base plate is designed to close the opening and to be connected to the first flow path forming body. Further, the first base plate forms a first through hole for connecting the first flow path and the second flow path.

### ADVANTAGEOUS EFFECTS OF INVENTION

According to the present invention, it is possible to improve the ease of assembly of power conversion apparatus.

### BRIEF DESCRIPTION OF DRAWINGS

FIG. 1 is an external perspective view of a power conversion apparatus 100 according to the present embodiment.

FIG. 2 is an exploded perspective view of the power conversion apparatus 100 according to the present embodiment.

FIG. 3 is an enlarged perspective view of electrical components provided between a first flow path forming body 110 and cover 107 shown in FIG. 2.

FIG. 4 is an enlarged, perspective view of a first base plate 400 and second flow path forming body 401 shown in FIG. 2.

FIG. 5 is an external perspective view of the first base plate 400 as seen from the arrow A of FIG. 4.

FIG. 6 is an external perspective view of a case 101 and the first flow path forming body 110.

FIG. 7 is an external perspective view showing the process of placing the first base plate 400 and the like in the case 101.

FIG. 8 is a cross-sectional view of the power conversion apparatus 100 shown in FIG. 1 as seen from the B plane in the arrow direction, in which the cover 107 and cover 108 are removed.

FIG. 9 is a cross-sectional view of the power conversion apparatus 100 shown in FIG. 1 as seen from the C plane in the arrow direction, in which the cover 107 and the cover 108 are removed.

### DESCRIPTION OF EMBODIMENTS

Hereinafter, an embodiment of a power conversion apparatus according to the present invention will be described with reference to the accompanying drawings. Note that the same reference numerals are designated to the same elements in each figure, and the overlapping description will be omitted.

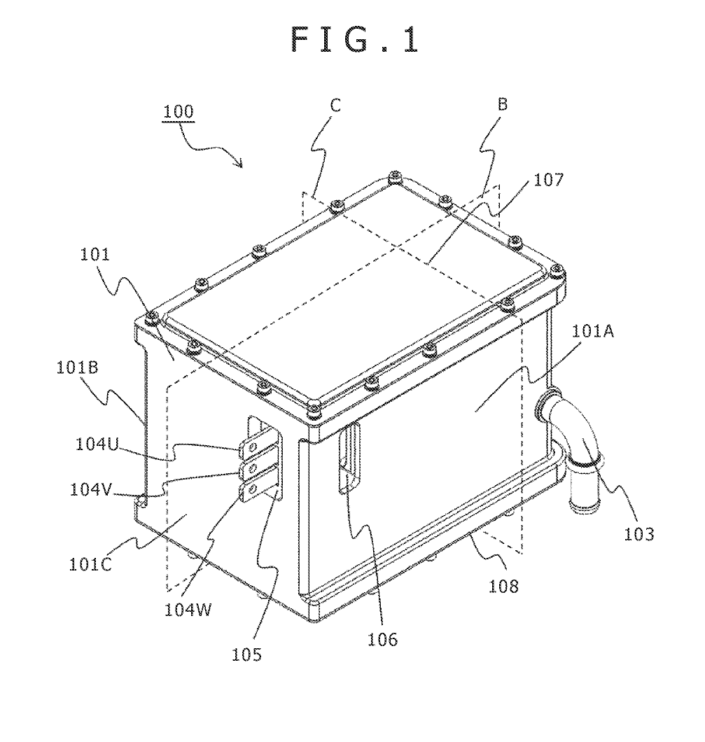

FIG. 1 is an external perspective view of a power conversion apparatus 100 according to the present embodiment.

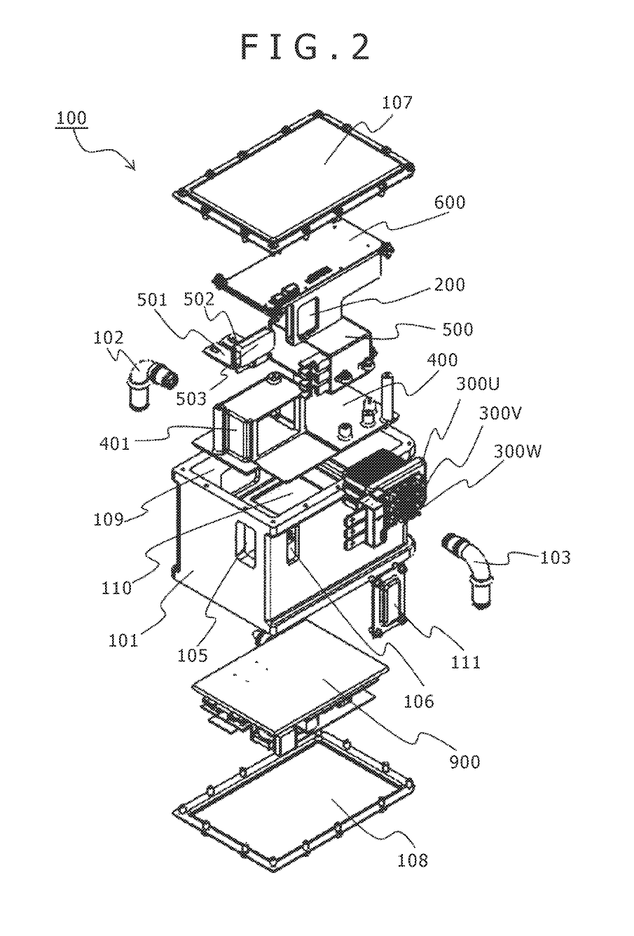

A case 101 houses a power semiconductor module 300U and the like described below. An outlet pipe 103 discharges a cooling refrigerant to the outside of the power conversion apparatus 100. The outlet pipe 103 is provided around a center portion in the height direction of a case side surface 101A. An inlet pipe 102 (see FIG. 2) is provided around a center portion in the height direction of a case side surface 101B that is formed on the opposite side of the case side surface 101A. The inlet pipe 102 guides the cooling refrigerant into the power conversion apparatus 100.

The case 101 forms an opening portion 105 on a case side surface 101C. An AC buss bar 104U, an AC bus bar 104V, and an AC bus bar 104W protrude from the case 101 to the outside of the case 101 through the opening portion 105. The AC bus bar 104U is a conductive member for transferring the AC current of the U phase, the AC bus bar 104V is a conductive member for transferring the AC current of the V phase, and the AC bus bar 104W is a conductive member for transferring the AC current of the W phase.

Further, the case 101 forms an opening portion 106 on the case side surface 101A. The opening portion 106 is formed at a position facing the connection part, of the AC bus bar 104U and the other conductors, the connection part of the AC bus bar 104V and the other conductors, and the connection part of the AC bus bar 104W and the other conductors. In this way, an operator and a work robot can perform the connection operation of the AC bus bars and each of the other conductors, through the opening portion 106.

A cover 107 closes a first insertion opening 109 (see FIG. 2) that is formed in the upper portion of the case 101. The first insertion opening 109 is formed to house the power semiconductor module 300U and the like described below.

A cover 108 closes a second insertion opening (not shown) formed in the lower portion of the case 101. The second insertion opening is formed to house a DC-DC converter 900 described below.

The power conversion apparatus 100 according to the present embodiment is mainly used in hybrid electric vehicles and electric vehicles, An example of a vehicle e system is described in Japanese Unexamined Patent Application Publication No. 2011-217550. Note that the power conversion apparatus 100 according to the present embodiment may be used in other applications in order to achieve the effect. For example, it may be used in an inverter for household appliances such as refrigerators and air conditioners for the purpose of improving the productivity and cooling performance. Further, the power conversion apparatus 100 may also be used in industrial inverter whose operating environment is similar to that of the vehicle inverter.

FIG. 2 is an exploded perspective view of the power conversion apparatus 100 according to the present embodiment. The first flow path forming body 110 is provided around a center portion in the height direction of the case 101. The first flow path forming body 110 is connected to the inlet pipe 102 and the outlet pipe 103.

The first base plate 400, the second flow path forming body 401, the power semiconductor modules 300U to 300W, the capacitor module 500, the drive circuit board 200, the control circuit board 600 and the like are provided between the first flow path forming body 110 and The cover 107.

The power semiconductor modules 300U to 300W, descried below, are designed to convert a direct current to an alternating current. The capacitor module 500, described below, is designed to smooth the DC voltage. The drive circuit board 200 is mounted with the drive circuit to output a drive signal to drive the power semiconductor modules 300U to 300W. The control circuit board 600 is mounted with the control circuit to output a control signal to the drive circuit board 200 in order to control the power semiconductor modules 300U to 300W. An example of these circuit systems is described in Japanese Unexamined Patient Application Publication 2011-217550.

The DC-DC converter 900 is provided between the first flow path forming body 110 and the cover 108. The DC-DC converter 900 is designed to convert the DC voltage. An example of the circuit system of the DC-DC converter 900 is described in Japanese Patent No. 4643695. The opening portion 106 described in FIG. 1 is closed by a cover 111.

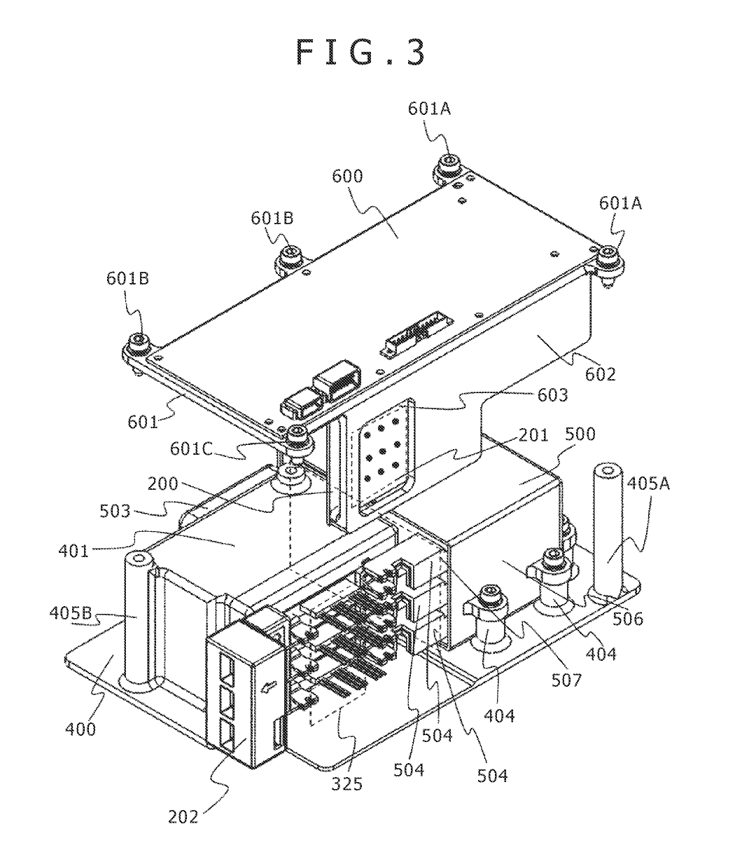

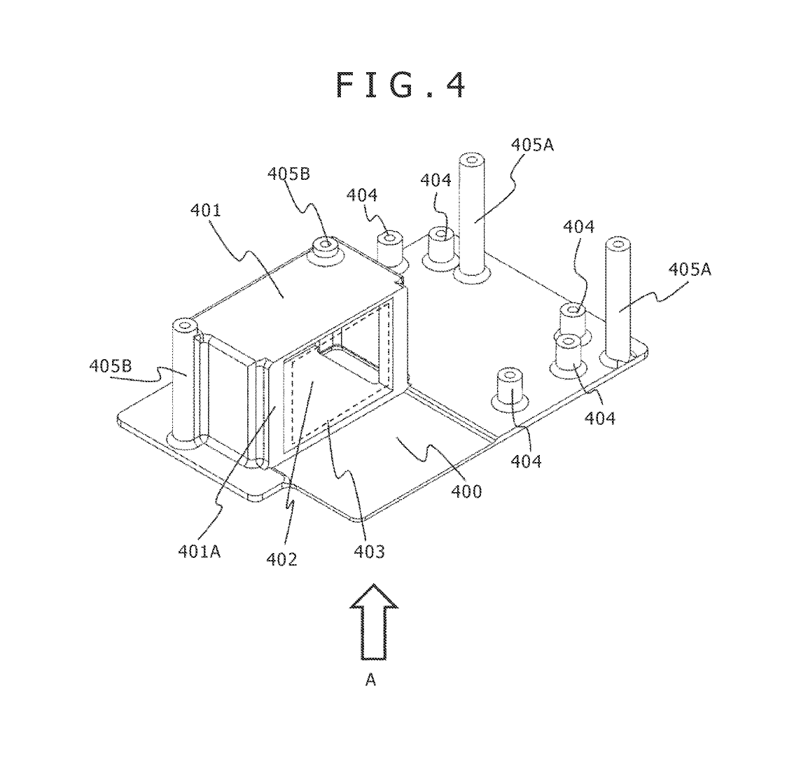

FIG. 3 is an enlarged perspective view of the electrical components provided between the first flow path forming body 110 and the cover 107 shown in FIG. 2. FIG. 4 is an enlarged perspective view of the first base plate 400 and the second flow path forming body 401 shown in FIG. 2.

The second flow path forming body 401 is mounted on the first base plate 400. The second flow path forming body 401 and she first base plate 400 may be integrally formed in order to improve the productivity and the thermal conductivity. As shown in FIG. 4, the second flow path forming body 401 forms a housing space 402 for housing the power semiconductor modules 300U to 300W. Further, the second flow path forming body 401 forms an insertion opening 403 in a side wall 401A, which leads to the housing space 402. In the present embodiment, the housing space 402 functions as a flow path for allowing the cooling refrigerant to flow therethrough. The insertion opening 403 according to the present embodiment is a single insertion opening designed for inserting the three power semiconductor modules 300U to 300W. However, the insertion opening may be provided for each of the multiple power conductor modules.

The first base plate 400 includes multiple support members 404 to fix she capacitor module 500. The capacitor module 500 is fixed in a state of being thermally connected to the first base plate 400 by the multiple support members 404. In this way, the heat generated in the capacitor module 500 is transferred to the first base plate 400 to be able to cool the capacitor module 500.

As shown in FIG. 3, a second base plate 601 is mounted with the control circuit board 600. The second base plate 601 includes a fixing part 601A that is connected to a support member 405A extending from the first base plate 400. In this way, the control circuit board 600 and other components are cooled by the first base plate 400 through the fixing part 601A and the support member 405A.

Further, the second base plate 601 supports a third base plate 602. The third base plate 602 protrudes in the arrangement direction of the first base plate 400, which is the direction perpendicular to the mounting surface of the control circuit board 600 in the second base plate 601.

The drive circuit board 200 is mounted on the surface of the third base plate 602 on the side on which the power semiconductor modules 300U to 300W are provided. In this way, the drive circuit board 200 is cooled by the third base plate 602 and the second base plate 601.

Further, the second base plate 601 includes a fixing part 601B that is connected to the support member 405 extending from the second flow path forming body 401. In this way, the second base plate 601 is thermally connected to the second flow path forming body 401 through the fixing part 601B. Thus, it is possible to achieve improvement of the cooling performance of the control circuit board 600 or the drive circuit board 200.

Further, the second base plate 601 and the third base plate 602 are configured by a material with high electrical conductivity such as aluminum. Then, the case 101 described in FIG. 1 is configured by a material, with high electrical, conductivity such as aluminum. The second base plate 601 includes a fixing part 601C that is directly connected to the case 101. Further, the control circuit board 600 is provided on the opposite side of the power semiconductor modules 300U to 300W with the second base board 601 interposed therebetween. In this way, the electromagnetic noise emitted from the power semiconductor modules 300U to 300W as well as the drive circuit board 200 is allowed to flow to the ground through the fixing part 601C and the like. Thus, it is possible to protect the control circuit board 600 from she electromagnetic noise.

In the present embodiment, the drive circuit board 200 is provided so that the mounting surface of the drive circuit faces the side wall 401A of the second flow path forming body 401. The power semiconductor modules 300U to 300W include a control terminal 325 connected to the drive circuit board 200 by passing through the insertion opening 403. In the present embodiment, the connection operation of the control terminal 325 and the drive circuit board 200 is performed before the power semiconductor modules 300U to 300W and the drive circuit board 200 are mounted in the case 101.

Note that the third base plate 602 forms the opening portion 603 that is formed at a position facing the connection part 201 of the control terminal 325 and the drive circuit board 200. In this way, it is possible to obtain the effect of removing the electromagnetic noise of the third base plate 602, and to achieve improvement in the connection workability.

A current sensor 202 is provided so that the AC bus bars 104U to 104W pass through the through hole formed in the current sensor 202. As shown in FIG. 2, the capacitor module 500 includes a resin sealant 503 for sealing a part of a DC positive electrode terminal 501 and a part of a DC negative electrode terminal 502. As shown in FIG. 3, one surface of the resin sealant 503 is brought into contact with one surface of the second flow path forming body 401. Because of this structure, not only the resin sealant 503 is cooled, but also the DC positive electrode terminal 501 and the DC negative electrode terminal 502 are cooled.

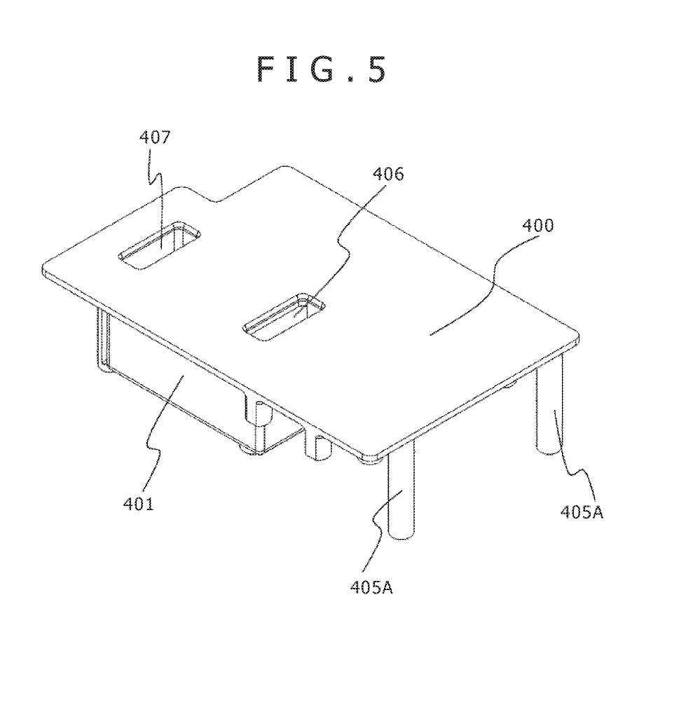

FIG. 5 is an external perspective view of the first base plate 400 a seen from the arrow A direction of FIG. 4. The first be plate 400 forms a first through hole 406 that leads to the housing space 402. Further, the first base plate 400 forms a second through hole 407 that leads to the housing space 402.

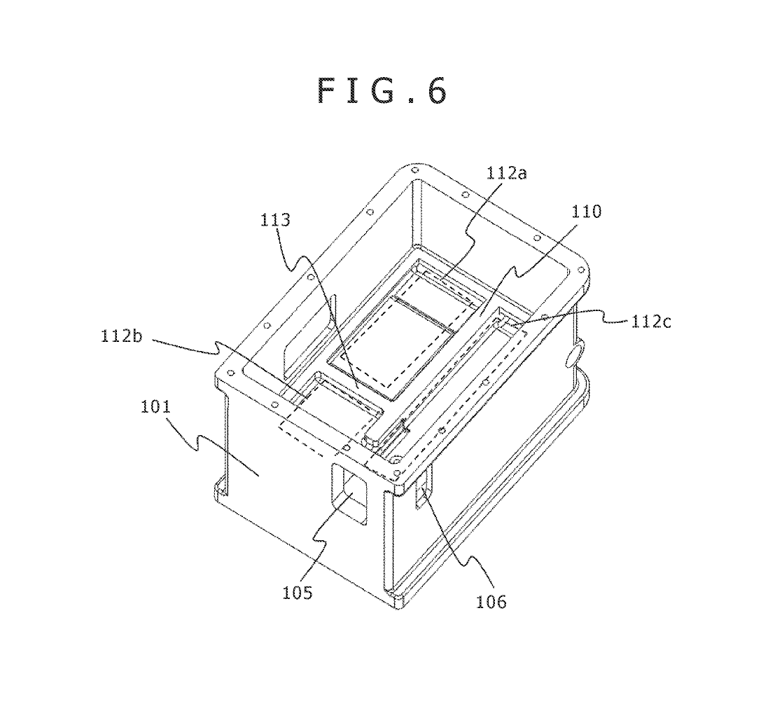

FIG. 6 is an external perspective view of the case 101 and the first flow path forming body 110. In the present embodiment, the first flow path forming body 110 is integrally formed with the case 101. For example, the case 101 and the first flow path forming body 110 are formed by casting. This eliminates the need for fixing member (bolts, and the like) and has also an effect of reducing the weight. In addition, the heat transfer between the case 101 and the first flow path forming body 110 is improved. As a result, the cooling performing of the whole power conversion apparatus 100 is improved.

The first flow path forming body 110 forms a flow path 112a that leads to the inlet pipe 102. The flow path 112a is formed so as to lead to the first through hole 406 shown in FIG. 5. At the same time, the first flow path forming body 110 forms a flow path 112b on a side portion of the flow path 112a with a partition wall 113 interposed therebetween. The flow path 112b is formed so as to lead to the second through hole 407 shown in FIG. 5. At the same time, the first flow path forming body 110 forms a flow path 112c that leads to the flow path 112b and leads to the outlet pipe 103. The flow path 112c is formed so that the flow direction of the refrigerant flowing through the flow path 112c is reverse to the flow direction of the refrigerant flowing through the flow path 112b.

The flow path 112a, the flow path 112b, and the flow path 112c lead no the opening portion that is closed by the first base plate 400 as described below.

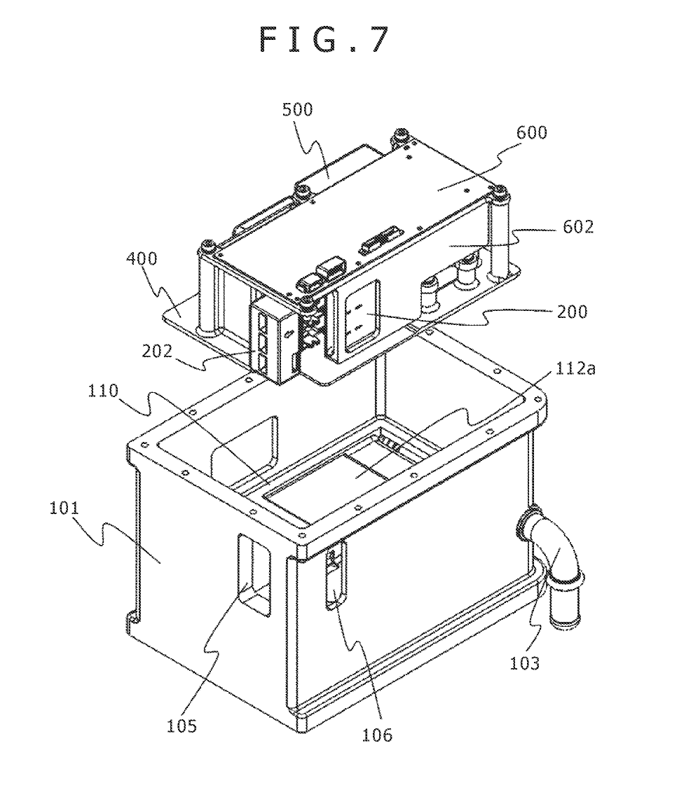

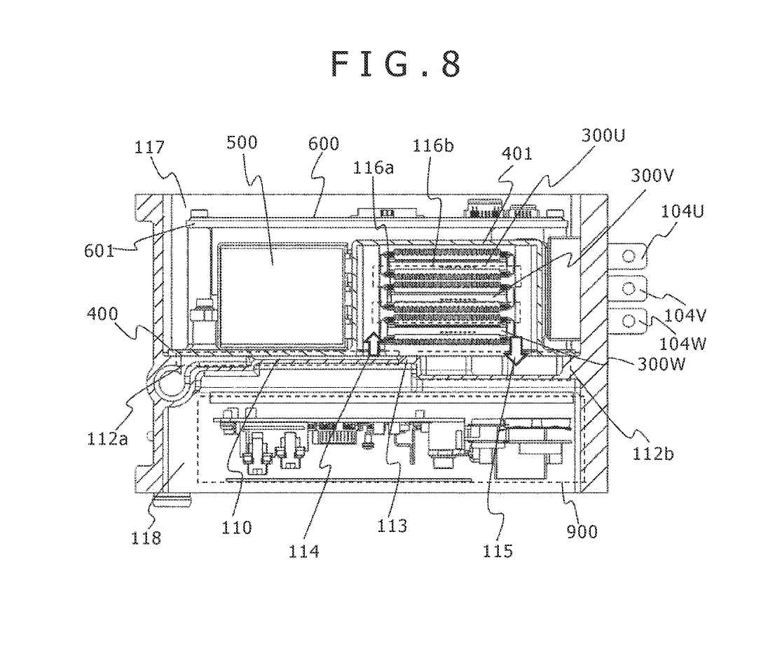

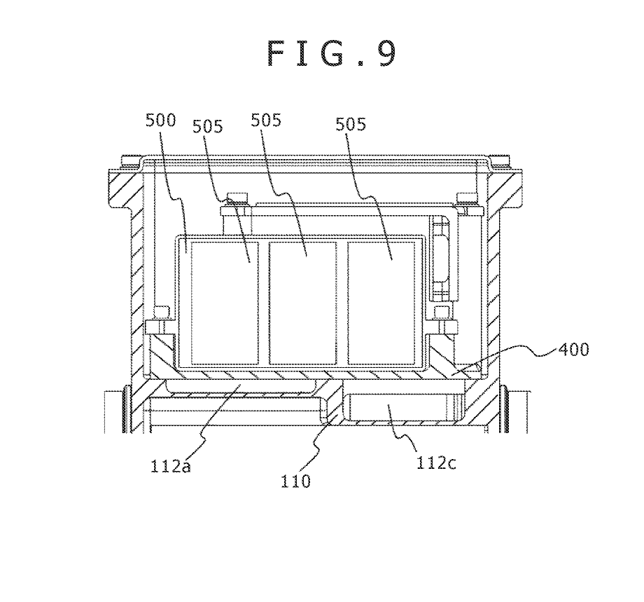

FIG. 7 is an external perspective view showing the process of placing the first base pate 400 and the like in the case 101. FIG. 8 is a cross-sectional view of the power conversion apparatus 100 shown in FIG. 1 as seen from the B plane in the arrow direction, in which the cover 107 and cover 108 are removed. FIG. 9 is a cross-sectional view of the power conversion apparatus 100 shown in FIG. 1 as seen from the C plane in the arrow direction, in which the cover 107 and the cover 108 are removed.

As shown in FIG. 7, the first base plate 400, on which the power semiconductor module 300U and the like are mounted, is provided in the first flow path forming body 110 and is connected to the first flow path forming body 110.

As shown in FIG. 8, the first base plate 400 is fixed to the first flow path forming body 110 so as to close the opening leading to the flow path 112a, the opening leading to the flow path 112b, and the opening leading to the flow path 112c. In this way, the first base plate 400 is directly brought into contact with the cooling refrigerant.

As shown in FIG. 8, the cooling refrigerant, flows to the housing space 402 of the second flow path forming body 401, as shown in a flow 114 of the cooling refrigerant by passing through the flow path 112a. The cooling refrigerant cools the power semiconductor modules 300U to 300W. Then, the cooling refrigerant flows from the housing space 402 to the flow path 112b as shown in a flow 115 of the cooling refrigerant. The power semiconductor modules 300U to 300W are configured by a cooling part placed in the housing space 402 and by an electrical connection part protruding outside the housing space 402. Because of the structure of the power semiconductor modules 300U to 300W, the protruding direction of the electrical connection part is the main factor to determine the dimensions of the power semiconductor modules 300U to 300W. For this reason, in order to reduce the dimension in the height direction of the power conversion apparatus 100, it is necessary to fully take into account the direction of the power semiconductor modules. Further, when the power conversion apparatus 100 is assembled, the power semiconductor modules and other components are installed from the opening portion of the case 101 of the power conversion apparatus 100, and then operations such as screwing, welding, and soldering are performed. At this time, it is difficult to perform such operations at a position deep from the opening portion at a position near the bottom of the case 101).

Thus, the first flow path forming body 110 and the second flow path forming body 401 are separately formed. Then, the second flow path forming body 401 is connected to the first base plate 400. Further, the main electrical components such as the power semiconductor modules 300U to 300W are mounted on the first base plate 400. The connection operation is performed outside the case 101 instead of inside the case 101. Then, the first base plate 400 on which the main electrical components are mounted is fixed to the second flow path forming body 401. In this way, the outside wall of the power conversion apparatus 100, namely, the wall of the case 101 is not present at the time of assembly. Thus, the directionality of the operation is eliminated and the flexibility in the design and assembly is increased. In addition, the flexibility in the direction of the electrical connection of the power semiconductor modules 300U to 300W is also increased. Thus, it is possible to arrange the power semiconductor modules 300U to 300W so that the protruding direction of the electrical connection part of the power semiconductor modules 300U to 300W runs to the inner wall of the case 101. In this way, it is possible to reduce the dimension in the height direction of the power conversion apparatus 100.

Further, the capacitor module 500 is mounted. Then, the fitting operation such as screwing, welding, and soldering of the electrical parts, as well as the fixing operation of the capacitor module 500 itself are performed. However, it has been difficult to perform the operation at a position deep from the opening portion of the case 101.

Thus, in the present embodiment, as shown in FIGS. 8 and 9, the capacitor module 500 is provided on the first base plate 400. In the capacitor module assembly, the capacitor module 500 is mounted on the first base plane 400, so that the case 101 has no wall and the directionality of the operation is eliminated. As a result, the flexibility in assembly such as screwing and welding is increased.

Further, the capacitor element 505 shown in FIG. 9 may be affected by the heat from the high output power semiconductor module, resulting in the reduction or failure in the performance of the capacitor element 505.

Thus, the second flow path forming body 110 is formed to the position in which the flow path 12a and the flow path 112c face the capacitor module 500. In this way, it is possible to cool the capacitor module 500. As a result, the performance and life of the capacitor element 505 can be increased to a desired level.

Further, in the present embodiment, the capacitor module 500 includes a capacitor case 506 for housing a part of the capacitor side terminal 504 and the capacitor element 505. The capacitor case 506 is formed with a capacitor side opening portion 507 with a capacitor side terminal 505 protruding outward. Further, the capacitor case 506 is provided on the first base plate 400 so that the capacitor side opening portion 507 faces the first flow path forming body 110 that houses the power semiconductor module.

Because of this structure, the wiring distance of the capacitor side terminal 505 connected to the power semiconductor module can be reduced. As a result, it is possible to reduce the inductance and reduce the heat generated by the capacitor side terminal 505 itself.

Further, in the present embodiment, the power semiconductor module 300V is provided at a position facing the first base plate 400 with the power semiconductor module 300W interposed therebetween. Then, a flow path space 116a through which the cooling refrigerant flows is formed between the power semiconductor module 300V and the second power semiconductor module 300W. Further, the power semiconductor module 300U is provided at a position facing the first base plate 400 with the power semiconductor module 300V and the power semiconductor module 300W interposed therebetween. Then, a flow path space 116b through which the cooling refrigerant flows is formed between the power semiconductor module 300U and the second power semiconductor module 300V.

Because of this structure, the power semiconductor modules 300U to 300W are directly brought into contact with the cooling refrigerant. At the same time, the cooling refrigerant flows through both surfaces of each power semiconductor module, so that it is possible to improve the cooling performance of the power semiconductor modules 300U to 300W.

Further, in the present embodiment, the case 101 is divided into a first housing space 117 and a second housing space 118 by the first flow path forming body 110. The first base plate 400 on which the main electrical components are mounted is housed in the first housing space 117. Or the other hand, the circuit components of the DC-DC converter 900 are housed in the second housing space 118 and are provided on the first flow path forming body 110. In this way, the inverter circuit is cooled by one surface of the first flow path forming body 110, and the DC-DC converter is cooled by one surface of the first flow path forming body 110, so that the cooling area of the first flow path forming body 110 can be effectively used. This can contribute to miniaturization of the whole apparatus.

Further in the present embodiment, the second base plate 601 of metal is provided at a position facing the first base 400 with the power semiconductor modules 300U to 300W interposed therebetween. Further, the second base plate 601 has a fixing part 601C connected to the case 101 of metal. Further, the control circuit board 600 is provided, at a position facing the power semiconductor modules 300U to 300W with the second base pate 601 interposed therebetween. In this way, the second base plate 601 blocks the electromagnetic noise emitted from the power semiconductor modules 300U to 300W. Thus, it is possible to protect the control circuit board 600 from the electromagnetic noise.

### LIST OF REFERENCE SIGNS

100 . . . power conversion apparatus, 101 . . . case, 101A . . . case side surface, 101B . . . case side surface, 101C . . . case side surface, 102 . . . inlet. pipe, 103 . . . outlet Pipe 104U . . . AC bus bar, 104V . . . AC bus bar, 104W . . . AC bus bar, 105 . . . opening portion, 106 . . . opening portion, 107 . . . cover, 108 . . . cover, 109 . . . first insertion opening, 110 . . . first flow path forming body, 111 . . . cover, 112a . . . flow path, 112b . . . flow path, 112c . . . flow path, 113 . . . partition wall, 114 . . . flow of cooling refrigerant, 115 . . . flow of cooling refrigerant, 116a . . . flow path space, 116b . . . flow path space, 200 . . . drive circuit board, 201 . . . connection part, 202 . . . current sensor, 300U . . . power semiconductor module, 300V . . . power semiconductor module, 300W . . . power semiconductor module, 325 . . . control terminal, 400 . . . first base plate, 401 . . . second flow path forming body, 401A . . . side wall, 402 . . . housing space, 403 . . . insertion opening, 404 . . . support member, 405A . . . support member, 405B . . . support member, 406 . . . first through hole, 407 . . . second through hole, 500 . . . capacitor module, 501 . . . DC positive electrode terminal, 502 . . . DC negative electrode terminal, 503 . . . resin sealant, 504 . . . capacitor side terminal, 505 . . . capacitor element, 506 . . . capacitor case, 507 . . . capacitor side opening portion, 600 . . . control circuit board, 601A . . . fixing part, 601B . . . fixing part, 601C . . . fixing part, 601 . . . second base plate, 602 . . . third base plate, 603 . . . opening portion, 900 . . . DC-DC converter

1. A power conversion apparatus comprising:
a power semiconductor module including a power semiconductor element designed to convert a direct current to an alternating current;
a first flow path forming body that forms a first flow path for allowing cooling refrigerant to flow therethrough;
a second flow path forming body that forms a second flow path for allowing cooling refrigerant to flow therethrough;
a first base plate for mounting the second flow path forming body thereon;
a drive circuit board mounted with a drive circuit to output a drive signal to drive the power semiconductor element; and
a case for housing the power semiconductor module, the first flow path forming body, the second flow path forming body, the first base plate, and the drive circuit board,
wherein the drive circuit board is provided so that the mounting surface of the drive circuit faces a side wall of the second flow path forming body,
wherein the second flow path forming body forms a housing space for housing the power semiconductor module,
wherein the second flow path forming body further forms an insertion opening that leads to the housing space on the side wall facing the mounting surface of the drive circuit,
wherein the power semiconductor module has a control terminal that is connected to the drive circuit board by passing through the insertion opening,
wherein the first flow path forming body is fixed to the case,
wherein the first flow path forming body further forms an opening portion leading to the first flow path,
wherein the first base plate is designed to close the opening portion and to be connected to the first flow path forming body, and
wherein the first base plate further forms a first through hole connecting the first flow path and the second flow path.

2. The power conversion apparatus according to claim 1, comprising a capacitor module for smoothing the DC voltage,
wherein the capacitor module is provided on the first base plate.

3. The power conversion apparatus according to claim 2,
wherein the first flow path is formed to a position facing the capacitor module.

4. The power conversion apparatus according to claim 2,
wherein the capacitor module comprises a capacitor element, a capacitor side terminal electrically coupled to the capacitor element, and a capacitor case for housing the capacitor element and the capacitor side terminal,
wherein the capacitor case forms a capacitor side opening portion with the capacitor side terminal protruding outward, and
wherein the capacitor case is also provided on the first base plate so that the capacitor side opening portion faces the second flow path forming body.

5. The power conversion apparatus according to claim 1,
wherein the power semiconductor module is configured by a first power semiconductor module and a second power semiconductor module,
wherein the second power semiconductor module is provided at a position facing the first base plate with the first power semiconductor module interposed therebetween, and
wherein a flow path space through which the cooling refrigerant flows is formed between the first power semiconductor module and the second power semiconductor module.

6. The power conversion apparatus according to claim 1,
wherein a second through hole for connecting the first flow path and the second flow path is formed on the first base plate, and
wherein the first flow path forming body has a partition wall provided between the first through hole and the second through hole so as to be brought into contact with the first base plate.

7. The power conversion apparatus according to claim 1,
wherein the power conversion apparatus includes a DC-DC converter circuit for converting a DC voltage,
wherein the case is divided into a first housing space and a second housing space by the first flow path forming body,
wherein the power semiconductor module, the second flow path forming body, and the first base plate are housed in the first housing space, and
wherein the DC-DC converter circuit is housed in the second housing space and is provided in the second flow path forming body.

8. The power conversion apparatus according to claim 1, comprising:
a second base plate of metal provided at a position facing the first base with the power semiconductor module interposed therebetween, the second base plate being fixed to the case; and
a control circuit board mounted with a control circuit to output a control signal to the drive circuit in order to control the power semiconductor element,
wherein the control circuit board is provided at a position facing the power semiconductor module with the second base plate interposed therebetween.

9. The power conversion apparatus according to claim 1,
wherein the first flow path forming body is integrally formed with the case.
